(19) United States
(12) Patent Application Publication
(10) Pub. No.: US 2009/0260869 A1
(43) Pub. Date: Oct. 22, 2009

(54) HIGH FREQUENCY DIGITAL A/V CABLE ASSEMBLY

(75) Inventor: Chang-Pin Wang, Yung-Ho City (TW)

Correspondence Address: SURE-FIRE ELECTRICAL CORPORATION, 2F-4, NO. 148, SEC. 4, CHUNG HSIAD E. ROAD, TAIPEI, TW

(73) Assignee: SURE-FIRE ELECTRICAL CORPORATION, Hsinchuang City (TW)

(21) Appl. No.: 12/244,776

(22) Filed: Oct. 3, 2008

(30) Foreign Application Priority Data
Apr. 17, 2008 (TW) 097206575

(51) Int. Cl. H05K 9/00; H01B 9/02

(52) U.S. Cl. 174/350; 174/102 R

(57) ABSTRACT

A high frequency digital A/V cable assembly includes a high frequency digital A/V cable, which comprises a plurality of core wires arranged in a parallel array, an insulation layer surrounding each core wire, a shielding layer surrounding the insulation layer at each core wire for isolating electromagnetic interference and an outer plastic sheath surrounding the shielding layer, a high frequency cable connector, and an adapter board electrically connected between the high frequency digital A/V cable and the high frequency cable connector to convert the pin configuration of the high frequency digital A/V cable into match with the high frequency cable connector.

This application claims the priority benefit of Taiwan patent application number 097206575 filed on Apr. 17, 2008.

### BACKGROUND OF THE INVENTION

1. Field of the Invention

The present invention relates to cables and more particularly, to a high frequency digital A/V cable assembly, which comprises a flat type high frequency digital A/V cable and a high frequency cable connector that is mounted with an adapter board for quick single-sided bonding of the core wires of the flat type high frequency digital A/V cable by means of an automatic wire bonding machine. The high frequency digital A/V cable assembly is a modularized design suitable for mass production to lower the cost.

2. Description of the Related Art

In recent years, audio and video application designs have been well developed. Nowadays, many audio and video products, such as DCD, DVD, digital versatile disc, high-definition digital TV, videophone, video conference system and the like are now common in our daily life. When compared to conventional techniques, these new system architectures utilize digital technology to process voice and image data. Subject to different requirements for application in different fields, different standards are established, modified and updated to improve digital signal transmission (without compression) in speed and quality so that people can enjoy better quality audio and video quality.

DisplayPort, DVI and HDMI are digital video interface standards designed to maximize the visual quality of digital display devices. A DisplayPort, DVI or HDMI connector is connectable to a\n adapter, set-top box, DVD player, PC, TV game machine, synthesized amplifier or digital audio equipment for long distance application to transmit audio video signals stably at a high speed, satisfying consumers' requirements.

A DisplayPort, DVI or HDMI connector can be used with a round or flat cable. When connecting a DisplayPort, DVI or HDMI connector to a cable, a circuit board is provided at the connector and electrically connected to the internal conducting terminals of the connector for the bonding of the transmission wires of the cable. However, the configuration of the conducting terminals of a DisplayPort, DVI or HDMI connector, the configuration of the metal contacts of the circuit board and the pin configuration of the cable to be connected are different. During installation, the transmission wires of the cable must be bonded to the respective metal contacts at the circuit board one after another in a proper order for perfect match. In order to approach one transmission wire to the matching metal contact at the circuit board, the transmission wire may have to be biased and tangled with other transmission wires. This mounting procedure is complicated, wasting much labor and time. Further, keeping transmission wires in a tangle relatively lowers the signal transmission quality.

Therefore, it is desirable to provide a measure that eliminates the aforesaid drawbacks.

### SUMMARY OF THE INVENTION

The present invention has been accomplished under the circumstances in view. It is the main object of the present invention to provide a high frequency digital A/V cable assembly, which allows quick bonding of the high frequency cable connector to the high frequency digital A/V cable by means of an automatic wire bonder, assuring excellent bonding quality for high quality signal transmission and saving much the installation time. It is another object of the present invention to provide high frequency digital A/V cable assembly, which has a modularized design suitable for mass production to save the cost. It is still another object of the present invention to provide a high frequency digital A/V cable assembly, which provides enhanced EMI protection.

According to one aspect of the present invention, the high frequency digital A/V cable assembly comprises a high frequency digital A/V cable, a high frequency cable connector, and an adapter board electrically connected between the high frequency digital A/V cable and the high frequency cable connector to convert the pin configuration of the high frequency digital A/V cable into match with the high frequency cable connector. The high frequency digital A/V cable comprises a plurality of core wires arranged in a parallel array, an insulation layer surrounding each core wire, a shielding layer surrounding the insulation layer at each core wire for isolating electromagnetic interference and an outer plastic sheath surrounding the shielding layer.

According to another aspect of the present invention, the adapter board comprises a first surface disposed at a top side thereof, a second surface disposed at a bottom side thereof, a first metal contact set and a jumper circuit set located on the first surface, a bonding contact set arranged on a rear side thereof and electrically connected with the first metal contact set and the jumper circuit set to constitute an array for the bonding of the core wires of the high frequency digital A/V cable, a second metal contact set arranged on the second surface and electrically connected to the jumper circuit set.

### BRIEF DESCRIPTION OF THE DRAWINGS

FIG. 1 is a perspective view of a high frequency digital A/V cable for high frequency digital A/V cable assembly in accordance with the present invention.

FIG. 2 is a sectional end view of the high frequency digital A/V cable shown in FIG. 1.

FIG. 3 is an exploded view of a high frequency digital A/V cable assembly in accordance with the present invention.

FIG. 4 corresponds to FIG. 3 when viewed from another angle.

FIG. 5 is an elevational assembly view of the high frequency digital A/V cable assembly in accordance with the present invention.

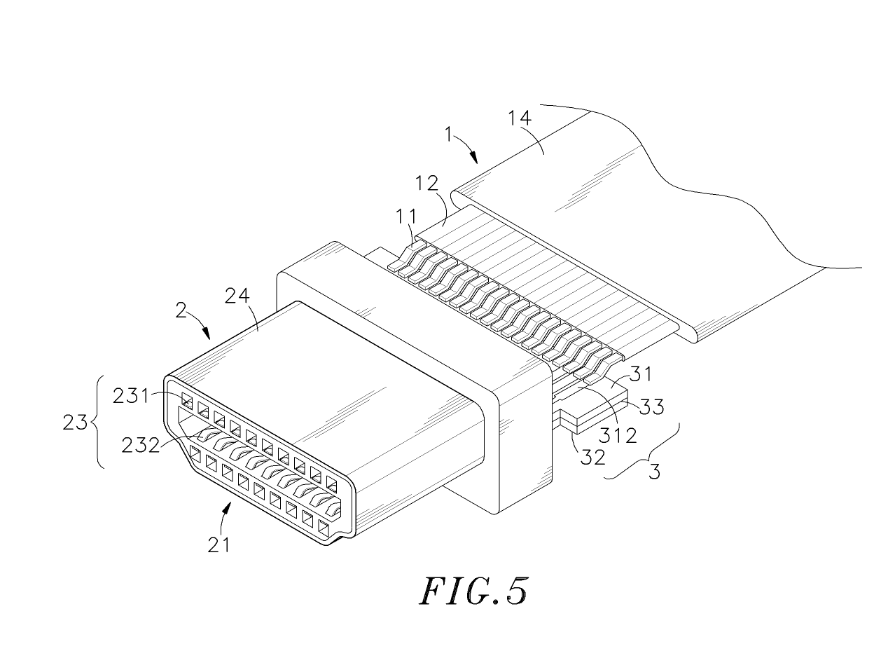

FIG. 6 is a pin configuration diagram of the high frequency digital A/V cable assembly in accordance with the present invention.

FIG. 7 is an exploded view of an alternate form of the high frequency digital A/V cable assembly in accordance with the present invention.

### DETAILED DESCRIPTION OF THE PREFERRED EMBODIMENT

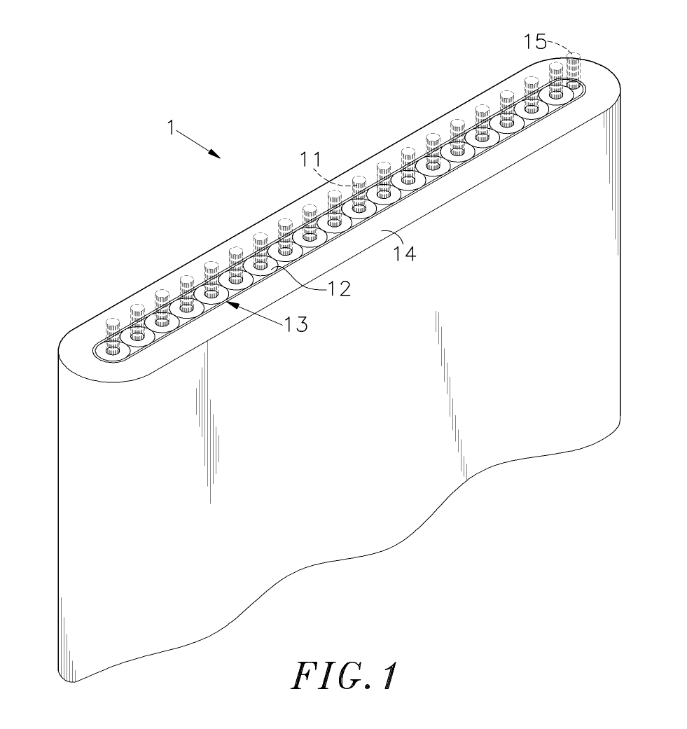

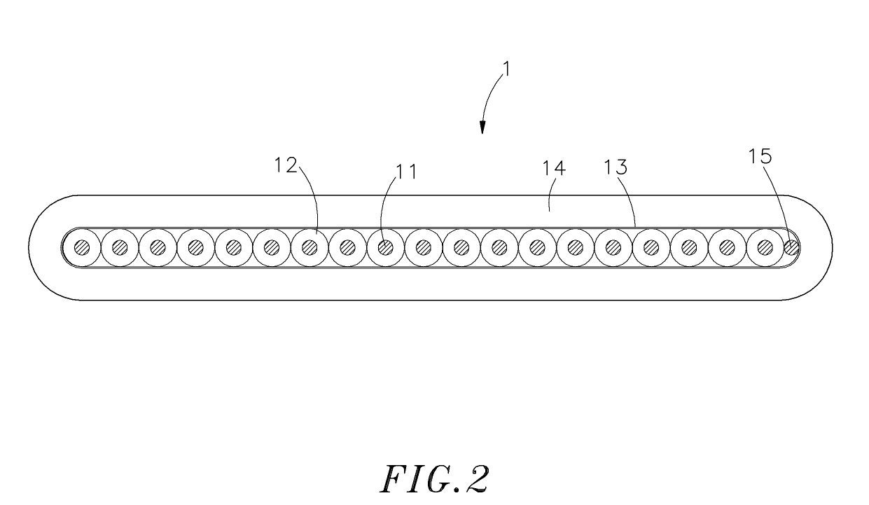

Referring to FIGS. 1 and 2, a high frequency digital A/V cable 1 in accordance with the present invention is shown comprising a plurality of core wires 11 arranged in a parallel array, an insulation layer 12 that surrounds each core wire 11, a shielding layer 13 that surrounds the insulation layer 12 at each of the core wires 11 for isolating electromagnetic interference, and an outer plastic sheath 14 that surrounds the shielding layer 13. The high frequency digital A/V cable 1 shows the shape of a flat cable.

The aforesaid core wires 11 can be formed of flexible aluminum, iron or copper. The insulation layer 12 is prepared from an electrically insulative material, for example, TPE (thermoplastic elastomer) or PE (polyethylene). The shielding layer 13 can be comprised of a tin foil, copper tape wrapped shield, or copper wire woven shield. The outer plastic sheath 14 can be formed of PVC (polyvinyl chloride), PE (polyethylene), PET (polyethylene terephthalate) or PP (polypropylene).

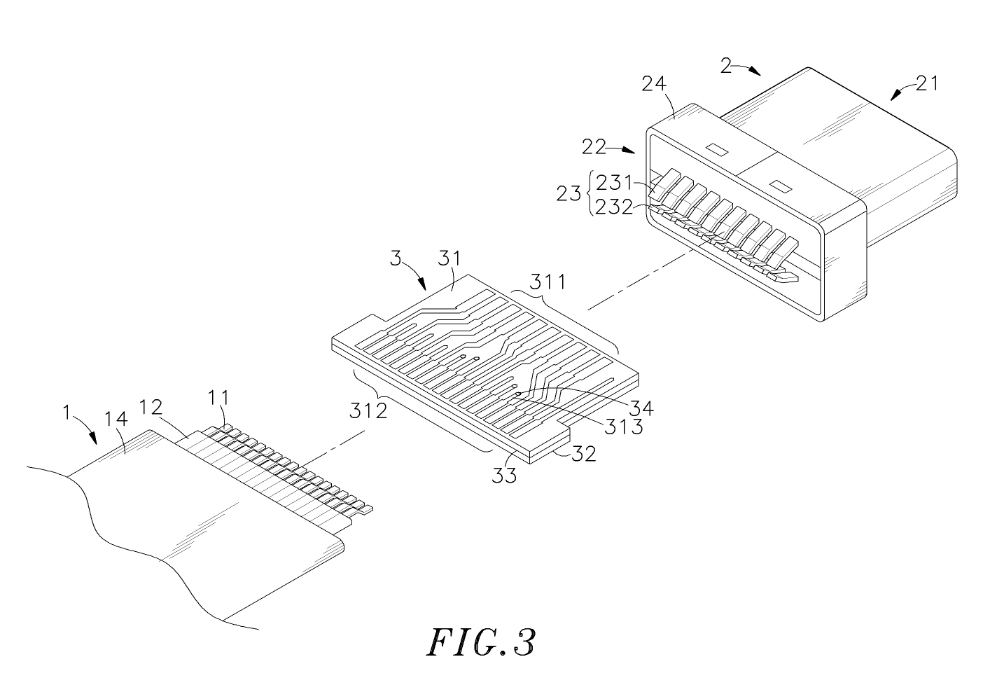

Referring to FIGS. 3˜6, the aforesaid high frequency digital A/V cable 1 is used with a high frequency cable connector 2, which has an abutting end 21 disposed at one end and connectable to an external electronic apparatus (not shown) and a bonding end 22 disposed at the other side and bonded with an adapter board 3 for the connection of the high frequency digital A/V cable 1. The high frequency cable connector 2 has a conducting terminal set 23 embedded therein. The conducting terminal set 23 comprises a plurality of first conducting terminals 231 and a plurality of second conducting terminals 232 respectively extending out of the bonding end 22. The adapter board 3 comprises a first surface 31 disposed at the top side, a second surface 32 disposed at the bottom side, a first metal contact set 311 and a jumper circuit set 313 located on the first surface 31, a bonding contact set 312 arranged on the rear side and electrically connected with the first metal contact set 311 and the jumper circuit set 313 for the bonding of the core wires 11 of the high frequency digital A/V cable 1, a second metal contact set 321 arranged on the second surface 32 and extending through the adapter board 3 and electrically connected to the jumper circuit set 313. Thus, the bonding contact set 312 to which the first metal contact set 311 is electrically connected is adapted for the bonding of the core wires 11 of the high frequency digital A/V cable 1.

After alignment between the core wires 11 of the high frequency digital A/V cable 1 and the bonding contact set 312 of the adapter board 3, an automatic wire bonding machine is operated to bond the core wires 11 of the high frequency digital A/V cable 1 to the bonding contact set 312 of the adapter board 3 automatically in a single-side bonding manner, achieving automatic mass production, raising the productivity and lowering the cost.

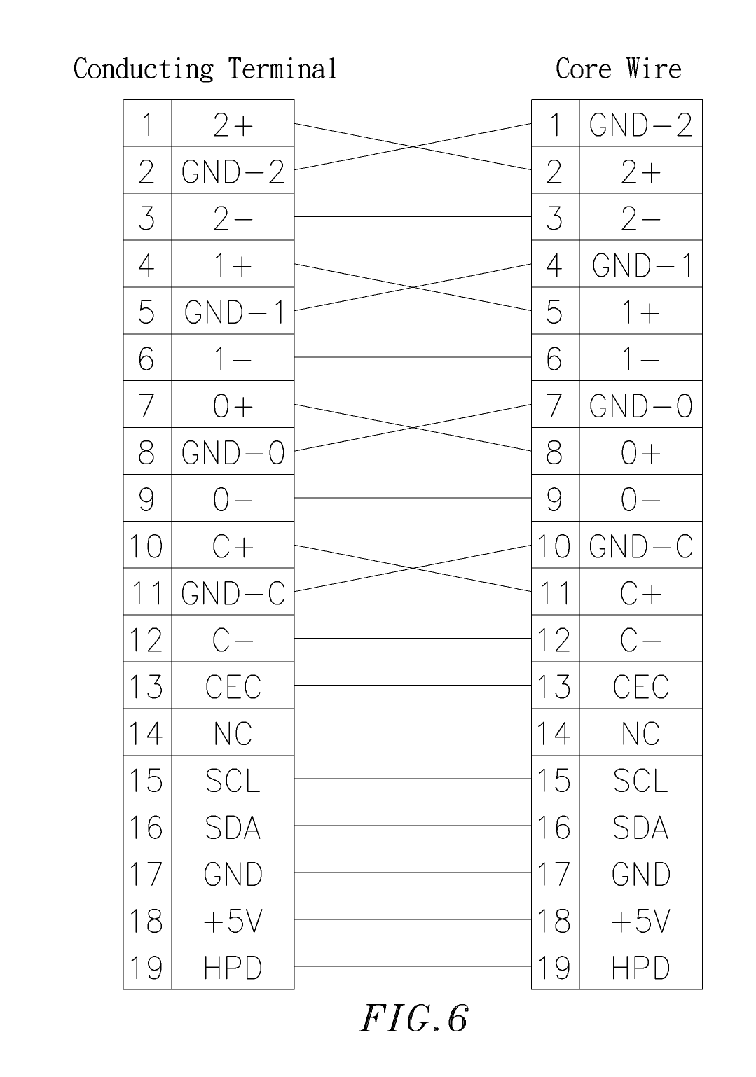

The number of the core wires 11 of the high frequency digital A/V cable 1 is 19. These core wires 11 are arranged on the same plane in an order from 1 through 19 to be: GND-2, 2+, 2−, GND-1, 1+, 1−, GND-0, 0+, 0−,GND-C, C+, C−, CEC, NC, SCL, SDA, GND, +5V and HPD respectively for bonding to the bonding contact set 312 of the adapter board 3. The high frequency cable connector 2 can be a HDMI (high-definition multimedia interface) connector. In this case, the conducting terminals of the conducting terminal set 23 of the high frequency cable connector 2 numbered from 1 through 19 to be: 2+, GND-2, 2−, 1+, GND-1, 1−, 0+, GND-0,0−,C+, GND-C, C−, CEC, NC, SCL, SDA, GND, +5V and HPD respectively for bonding to the first metal contact set 311 on the first surface 31 of the adapter board 3 the second metal contact set 321 on the second surface 32 of the adapter board 3 (see FIGS. 3, 4 and 6).

Except HDMI, the high frequency cable connector 2 can be alternately made in the form of a DisplayPort or DVI connector. In case of a DVI connector, at least 24 conducting terminals are arranged in three rows. In case of a DisplayPort connector, 20 conducting terminals are arranged in two rows. By means of the adapter board 3, the high frequency cable connector 2, either in HDMI, DisplayPort or DVI form, can be connected to the high frequency digital A/V cable 1 by means of pin-insertion bonding or surface mounting technique.

Thus, during connection between the high frequency digital A/V cable 1 and the high frequency cable connector 2, the adapter board 3 is used for bonding. By means of the matching design between the adapter board 3 and the high frequency digital A/V cable 1 and the matching design between the adapter board 3 and the high frequency cable connector 2, the high frequency digital A/V cable 1 and the high frequency cable connector 2 are electrically connected together. By means of the matching arrangement, the high frequency digital A/V cable 1 can be a flat cable. If the core wires 11 of the high frequency digital A/V cable 1 are arranged subject to a different pin configuration, the bonding contact set 312 of the adapter board 3 can be designed to match the pin configuration of the core wires 11. By means of the configuration matching design between the bonding contact set 312 of the adapter board 3 and the core wires 11 of the high frequency digital A/V cable 1, direct alignment is easily done for quick bonding, avoiding tangling of core wires 11 during bonding and saving much the installation time. Therefore, the invention has good applicability and high expansibility characteristics. Further, the modularized design of the present invention is suitable for mass production to save the cost.

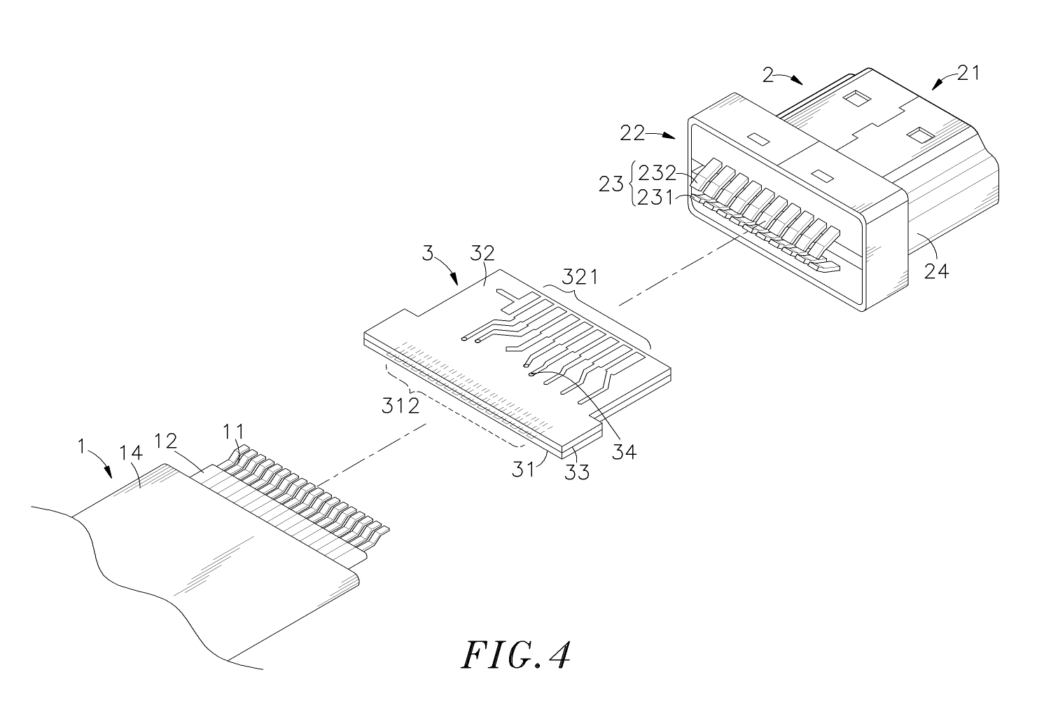

Further, when connecting the abutting end 21 of the high frequency digital A/V cable 1 to an external electronic product, the metal ground plane 33 of the adapter board 3 insolates interference produced during signal transmission through the circuits on the top and bottom sides of the adapter board 3 (see FIG. 4), lowering crosstalk noise. Further, the adapter board 3 itself has electromagnetic wave isolation function. Therefore, the invention provides enhanced EMI protection.

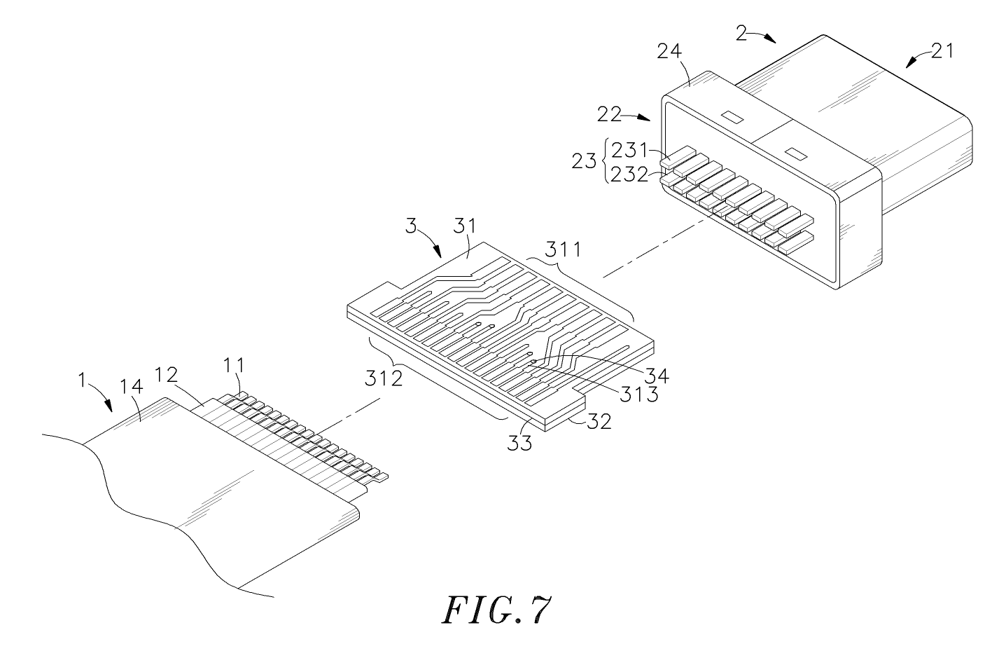

Referring to FIG. 7, the gap between the upper row of first conducting terminals 231 and bottom row of second conducting terminals 232 of the conducting terminal set 23 of the high frequency cable connector 2 can be designed subject to the thickness of the adapter board 3. Further, the first conducting terminals 231 and the second conducting terminals 232 horizontally extend out of the bonding end 22 at two different elevations. During installation, the adapter board 3 is directly inserted into the space between the first conducting terminals 231 and the second conducting terminals 232. After insertion of the adapter board 3 into the space between the first conducting terminals 231 and the second conducting terminals 232, the first conducting terminals 231 and the second conducting terminals 232 are respectively attached to the respective contacts at the adapter board 3, and thus the first conducting terminals 231 and second conducting terminals 232 of the high frequency cable connector 2 can be directly bonded to the adapter board 3 by an automatic bonding machine, saving much the installation time.

The aforesaid high frequency digital A/V cable 1 further comprises a grounding wire 15. The grounding wire 15 can be a tinned copper wire, copper wire or silver-plated metal wire disposed outside insulation layer 12 and peripherally abutted against the shielding layer 13. The adapter board 3 further comprises a plurality of via holes 34 (see FIG. 4) that extend through the adapter board 3 and electrically connected between the second metal contact set 321 on the second surface 32 of the adapter board 3 and the ends of the jumper circuit set 313 to which the first metal contact set 311 is electrically connected. By means of the via holes 34, crosstalk noise is guided from the grounding wire 15 of the high frequency digital A/V cable 1 to the metal ground plane 33 of the adapter board 3 and then eliminated. Therefore, audio and video signals are stably transmitted through the high frequency digital A/V cable 1, the adapter board 3 and the high frequency cable connector 2 to the electronic apparatus for output, and therefore the electronic apparatus can display high quality images.

Further, the high frequency cable connector 2 is covered with a metal shielding shell 24 (see FIG. 4) for protection against external electromagnetic interference. According to the present preferred embodiment, the high frequency cable connector 2 is a male connector. However, this is not a limitation. Alternatively, the high frequency cable connector 2 can be made in the form of a female connector.

The scope of the present invention to be protected is that the high frequency digital A/V cable 1 is a flat cable connected with a high frequency cable connector 2 through a an adapter board 3, comprising a plurality of core wires 11 arranged in a parallel array, an insulation layer 12 that surrounds each core wire 11, a shielding layer 13 that surrounds the insulation layer 12 at each of the core wires 11 for isolating electromagnetic interference, and an outer plastic sheath 14 that surrounds the shielding layer 13, wherein the structural design of the adapter board 3 converts the configuration of the core wires 11 of the high frequency digital A/V cable 1 to match with the configuration of the first conducting terminals 231 and second conducting terminals 232 of the high frequency cable connector 2 for quick bonding by means of an automatic wire bonder, assuring excellent bonding quality for high quality signal transmission and saving much the installation time.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A high frequency digital A/V cable assembly comprising a high frequency digital A/V cable and a high frequency cable connector connected to one end of said high frequency digital A/V cable, wherein said high frequency digital A/V cable comprises a plurality of core wires arranged in a parallel array, an insulation layer respectively surrounding each said core wire, a shielding layer surrounding the insulation layer at each said core wire for isolating electromagnetic interference, and an outer plastic sheath surrounding said shielding layer.

2. The high frequency digital A/V cable assembly as claimed in claim 1, wherein the number of said core wires of said high frequency digital A/V cable is 19, and said high frequency cable connector is a HDMI connector.

3. The high frequency digital A/V cable as claimed in claim 1, wherein the number of said core wires of said high frequency digital A/V cable is 20, and said high frequency cable connector is a DisplayPort male connector.

4. The high frequency digital A/V cable assembly as claimed in claim 1, wherein the number of said core wires of said high frequency digital A/V cable is at least 24, and said high frequency cable connector is a DVI male connector.

5. The high frequency digital A/V cable assembly as claimed in claim 1, wherein said core wires of said high frequency digital A/V cable are flexible metal wires selected from a material group of aluminum, iron and copper.

6. The high frequency digital A/V cable assembly as claimed in claim 1, wherein said insulation layer is selected from a material group of thermal plastic elastomer and polyethylene.

7. The high frequency digital A/V cable assembly as claimed in claim 1, wherein said shielding layer is selected from a material group of tin foil, copper tape wrapped shield and copper wire woven shield.

8. The high frequency digital A/V cable assembly as claimed in claim 1, wherein said outer plastic sheath is selected from a material group of PVC (polyvinyl chloride), PE (polyethylene), PET (polyethylene terephthalate) and PP (polypropylene).

9. The high frequency digital A/V cable assembly as claimed in claim 1, wherein said high frequency digital A/V cable further comprises a grounding wire disposed within said shielding layer at one lateral side relative to said insulation layer and peripherally abutted against said shielding layer.

10. The high frequency digital A/V cable assembly as claimed in claim 9, wherein said grounding wire is selected from a material group of tinned copper wire, copper wire and silver-plated metal wire.

11. The high frequency digital A/V cable assembly as claimed in claim 1, further comprising an adapter board adapted for electrically connecting said wire cores of said high frequency digital A/V cable to conducting terminals of said high frequency cable connector.

12. The high frequency digital A/V cable assembly as claimed in claim 11, wherein said adapter board comprises a first surface disposed at a top side thereof, a second surface disposed at a bottom side thereof, a first metal contact set and a jumper circuit set located on said first surface, a bonding contact set arranged on a rear side thereof and electrically connected with said first metal contact set and said jumper circuit set to constitute an array for the bonding of said core wires of said high frequency digital A/V cable, a second metal contact set arranged on said second surface and electrically connected to said jumper circuit set.
